(19) United States
(12) Patent Application Publication
(10) Pub. No.: US 2013/0153981 A1
(43) Pub. Date: Jun. 20, 2013

(54) NONVOLATILE MEMORY DEVICES AND METHODS OF MANUFACTURING THE SAME

(71) Applicant: Kyoung Rok HAN, Gyeonggi-do (KR)

(72) Inventor: Kyoung Rok HAN, Gyeonggi-do (KR)

(21) Appl. No.: 13/603,299

(22) Filed: Sep. 4, 2012

(30) Foreign Application Priority Data
Dec. 20, 2011 (KR) 10-2011-0138199

(51) Int. Cl. H01L 29/788; H01L 21/28

(52) U.S. Cl. 257/321; 438/586; 257/E29.3; 257/E21.209

(57) ABSTRACT

A nonvolatile memory device, and method of forming the same, discloses a semiconductor device including floating gates that each have a first region that overlaps with a corresponding junction and that each have a second region that does not overlap the corresponding junction. The first region and the second region have different work functions.

### CROSS-REFERENCE TO RELATED APPLICATION

Priority to Korean patent application number 10-2011-0138199 filed on Dec. 20, 2011, the entire disclosure of which is incorporated by reference herein, is claimed.

### BACKGROUND

Embodiments of this disclosure relate to nonvolatile memory devices and methods of manufacturing the same and, more particularly, to nonvolatile memory devices including floating gates and methods of manufacturing the same.

A nonvolatile memory device retains data stored therein although the supply of power is blocked. The nonvolatile memory device is classified into a charge-storage-type, a charge-trap-type, etc. depending on a data storage method. The floating-gate-type nonvolatile memory device stores data by injecting or discharging data into or from the conduction band of a floating gate, and the charge-trap-type nonvolatile memory device stores data by injecting or discharging data into or from a deep level trap site within a charge trap layer.

FIG. 1 shows a cross-sectional view of a conventional nonvolatile memory device.

As shown in FIG. 1, the conventional nonvolatile memory device includes gate patterns, each including a tunnel insulating layer 11, a floating gate 12, a charge blocking layer 13, and a control gate 14 that are alternately stacked over a substrate 10. Furthermore, source and drain regions 15 are provided in the substrate 10 on both sides of each gate pattern, and the source and drain regions 15 partially overlap with the gate pattern.

The substrate 10 is P-type, and the source and drain regions 15 are N-type. Furthermore, the floating gate 12 is N-type or P-type.

If the floating gate 12, however, is N-type, then there may be problems in that a threshold voltage of a memory cell may be lowered and leakage current may be generated as a result of a short channel effect in which the channel length of the memory cell is shortened.

In contrast, if the floating gate 12 is P-type, the electron-hole pairs may be generated in regions in which the floating gate 12 overlaps with the source and drain regions 25 because a P-type polysilicon layer has a higher work function than a N-type polysilicon layer. As a result, gate-induced drain leakage (GIDL) may be generated. For example, as shown in FIG. 1, a negative verify voltage may be supplied to the control gate 14 of a memory cell on which a verify operation will be performed. A positive read voltage may be supplied to memory cells adjacent to the memory cell on which the verify operation will be performed. In this case, carriers generated in the overlap regions may be trapped in the floating gates 12 or in the tunnel insulating layers 11 of the adjacent memory cells, thereby generating disturbance.

### BRIEF SUMMARY

An exemplary embodiment of this disclosure provides nonvolatile memory devices suitable for preventing a short channel effect and GIDL and methods of manufacturing the same. In an aspect of this disclosure, a nonvolatile memory device includes gate patterns, each comprising a tunnel insulating layer, a floating gate, a charge blocking layer, and a control gate, formed over a substrate; and junctions formed in the substrate, where each of the junctions is to overlap with at least one of the floating gates, and where each of the floating gates includes a first region that overlaps a corresponding junction, and a second region, that does not overlap the corresponding junction, and where the first region and the second region have different work functions.

In another aspect of this disclosure, a method of manufacturing a nonvolatile memory device includes forming, over a substrate, gate patterns, each comprising a tunnel insulating layer, a floating gate, a charge blocking layer, and a control gate; and performing a surface treatment process on each of the floating gates, the surface treatment resulting in a first region of each of the floating gate and a second region of each of the floating gate having different work functions.

In yet another aspect of this disclosure, a method of manufacturing a nonvolatile memory device includes forming a tunnel insulating layer on a substrate; forming a first conductive layer for floating gates on the tunnel insulating layer, where the first conductive layer comprises two or more layers each having a different work function; forming a charge blocking layer on the first conductive layer; forming a second conductive layer for control gates on the charge blocking layer; and forming gate patterns by etching the second conductive layer, the charge blocking layer, and the first conductive layer.

### BRIEF DESCRIPTION OF THE DRAWINGS

FIG. 1 shows a cross-sectional view of a conventional nonvolatile memory device;

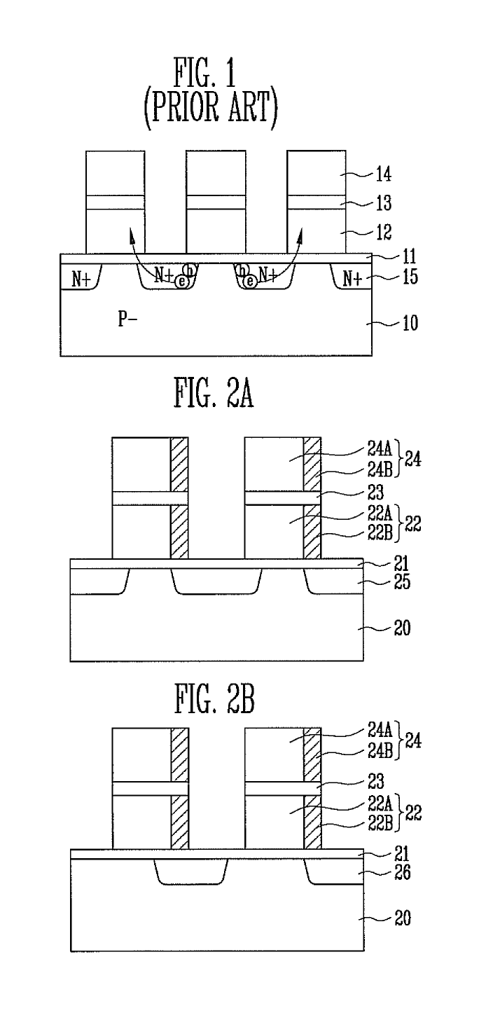

FIGS. 2A and 2F show cross-sectional views of a nonvolatile memory device according to a first embodiment of this disclosure;

FIGS. 3A and 3B are cross-sectional views illustrating a method of manufacturing a nonvolatile memory device according to a second embodiment of this disclosure;

FIGS. 4A and 4B are cross-sectional views illustrating a method of manufacturing a nonvolatile memory device according to a third embodiment of this disclosure;

FIGS. 5A and 5B are cross-sectional views illustrating a method of manufacturing a nonvolatile memory device according to a fourth embodiment of this disclosure;

FIGS. 6A to 6C are cross-sectional views illustrating a method of manufacturing a nonvolatile memory device according to a fifth embodiment of this disclosure;

FIG. 7 shows the construction of a memory system according to one embodiment of this disclosure; and

FIG. 8 shows the construction of the construction of a computing system according to one embodiment of this disclosure.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

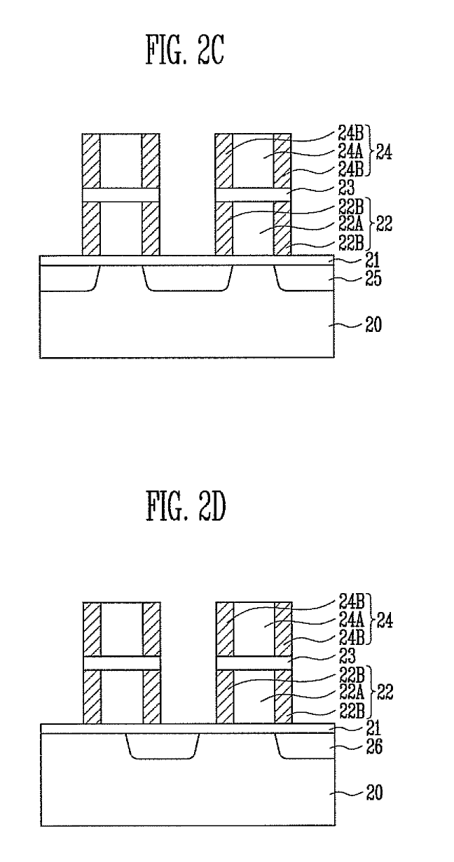

FIGS. 2A and 2F show cross-sectional views of a nonvolatile memory device according to a first embodiment of this disclosure.

As shown in FIG. 2A to 2F, the nonvolatile memory device according to the first embodiment of this disclosure includes gate patterns in each of which a tunnel insulating layer 21, a floating gate 22, a charge blocking layer 23, and a control gate 24 are stacked over a substrate 20.

Furthermore, junctions 25 are provided in the substrate 20 on both sides of each of the gate patterns. The junctions 25, 26 may be source or drain regions and are formed so that they partially overlap the gate patterns. As shown in FIGS. 2A, 2C, and 2E, the junctions 25 may be symmetrically formed on the basis of the gate pattern so that they overlap with both sidewalls of the gate pattern. In some embodiments, as shown in FIGS. 2B, 2D, and 2F, the junctions 26 may be asymmetrically formed on the basis of the gate pattern so that they overlap with only one sidewalls of the gate pattern.

The floating gate 22 is formed to have a different work function depending on a region. A first region, in which the floating gate 22 overlaps a corresponding one of the junctions 25, 26 may have a different work function then a second region that is different than the first region. For example, the first region may be at least one sidewall region of the floating gate 22. In particular, the first region may be formed to have a lower work function than the second region. In this case, an electric field between the floating gate 22 and the overlapped portion of the corresponding junction 25, 26 can be reduced. Therefore GIDL can be reduced.

The floating gate 22 may include two or more layers having different work functions. For example, the second region may be formed of a first material layer 22A having a higher work function than a material of the corresponding junction 25, 26, and the first region may be formed of a second material layer 22B having a smaller work function than the material of the corresponding junction 25, 26.

The first material layer 22A and the second material layer 22B are formed to come in contact with each other, thus forming the floating gate 22. For example, as shown in FIGS. 2A, 2B, 2E, and 2F, the first material layer 22A may be formed on one side of the second material layer 22B. In some embodiments, as shown in FIGS. 2C and 2D, the second material layer 22B may be formed on both sides of the first material layer 22A.

The first material layer 22A and the second material layer 2B may be formed by separate processes or may be formed as a single layer and be processed to have different work functions by an ion implantation process, a plasma doping process, or a silicidation process.

For example, the floating gate 22 may include the first material layer 22A, including impurities of a first type, and the second material layer 22B, including impurities of a second type, different from the first type. The second material layer 22B is placed in a region in which it overlaps with the corresponding junction 25, 26, and includes the exact same type of impurity as does the corresponding junction 25, 26. The first material layer 22A is placed in a region that does not overlap with the corresponding junctions 25, 26, and includes a different type of impurity than does corresponding junction 25, 26.

In this exemplary embodiment, the first material layer 22A and the second material layer 22B have different work functions depending on the type of doped impurity. If the first material layer 22A is doped with a P-type impurity, such as boron (B), and the second material layer 22B is doped with an N-type impurity, such as phosphorous (P), then the second material layer 22B will have a lower work function than the first material layer 22A. As a result, a short channel effect can be prevented by the P-type first material layer 22A and an electric field between the N-type junction and the N-type second material layer 22B can be reduced, thereby preventing the generation of GIDL.

In another example, the first material layer 22A may be a conductive layer and the second material layer 22B may be a silicide layer. The second material layer 22B is placed in a region in which it overlaps with the corresponding junction 25, and the first material layer 22A is placed in a region in which it does not overlap with the corresponding junction 25, 26. If the first material layer 22A is a polysilicon layer, the second material layer 22B, which is the silicide layer, has a lower work function than the first material layer 22A. As a result, the generation of GIDL can be prevented because an electric field between the junctions 25, 26 and the second material layer 22B is reduced.

In one exemplary embodiment, shown in FIGS. 2E and 2F, only the floating gate 22 may include two or more layers having different work functions, while the control gate only includes one layer. In some exemplary embodiments, as shown in FIG. 2A to 2D, the control gate 24 and the floating gate 22 may be formed to have the same structure. That is, both the floating gate 22 and the control gate 24 may include two or more layers having different work functions, and the first region, which overlaps with the corresponding junction 25, 26 may have a lower work function than the second region

For example, the control gate 24 may include a first material layer 24A, including impurities of a first type, and a second material layer 24B, including impurities of a second type different from the first type. In another example, the first material layer 24A, of control gate 24, may be a conductive layer and the second material layer 24B may be a silicide layer.

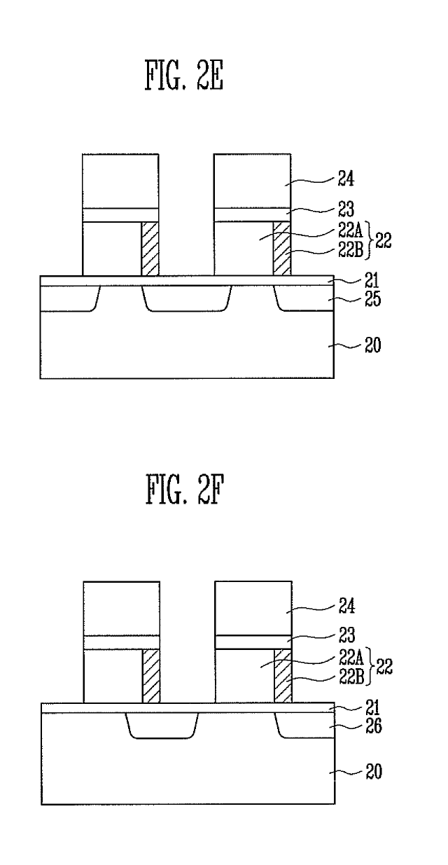

FIGS. 3A and 3B are cross-sectional views illustrating a method of manufacturing a nonvolatile memory device according to a second embodiment of this disclosure.

As shown in FIG. 3A, gate patterns, each including a tunnel insulating layer 31, a floating gate 32, a charge blocking layer 33, and a control gate 34, stacked over a substrate 30, are formed. The at least one of the floating gate 32 or the control gate 34 may be formed of a first material layer that has been doped with a first type of impurity. For example, a polysilicon layer may be doped with a P-type impurity. The floating gate 32 may be formed to a thickness of about 1 to about 100 nm.

A reoxidization process may be performed on the resultant structure in which the gate patterns have been formed. As a result of the reoxidization process, an oxide layer having a thickness of 1 to 10 nm is formed on a surface of the gate patterns.

Next, a first region of the floating gate 32 is subject to a surface processing so that it has a different work function than a second region, which is different than the first region, of the floating gate. For example, one or more sidewalls of the floating gate 32 may be subjected to the surface processing. In the second embodiment, a second type of impurity, for example, an N-type impurity, is doped into the floating gates 32 that have been exposed to the sidewalls of the gate patterns by the surface processing. Here, the second type of impurity is doped into the sidewalls of the floating gates 32 to a specific thickness, thereby forming second material layers 32B as shown in FIG. 3A. As a result, the floating gates 32 each include a first material layer 32A having the first type of impurity and a second material layer 32B having the second type of impurity, are formed.

The second type of impurity may be doped by an ion implantation process or a plasma doping process. If the second type of impurity is doped by the ion implantation process, a tilt ion implantation process is performed so that ions are implanted at a specific angle. Here, while forming the second material layers 32B, a junction (not shown) may be formed in the substrate 30 between the gate patterns. If the tilt ion implantation process is used, asymmetrical junctions can be easily formed. Furthermore, even if the plasma doping process is used, the second material layers 32B and junctions can be formed at the same time. In some embodiments, after the second material layers 32B are formed by the ion implantation process or the plasma doping process, the junctions may be formed by an additional process.

Furthermore, when doping the second type of impurity, conditions for the ion implantation process or the plasma doping process are controlled so that the second material layers 32B are formed in regions that overlap the junctions. For example, the second type of impurity may be doped at a concentration of about 10¹² to about 10¹⁶ atoms/cm³, using an energy of 0.1 to 10 k EV.

Meanwhile, when doping the second type of impurity, the impurity may also be doped into the sidewalls of the control gates 34. In this case, the control gates 34, each including a first material layer 34A, which has been doped with the first type of impurity and a second material layer 34B, which has been doped with the second type of impurity, are formed. The control gate 34 and the floating gate 32 may have the same structure.

The exemplary embodiment, shown in FIGS. 3A and 3B, show that the second material layers 32B and 34B are formed on only one of the sidewalls of the floating gates 32 and the control gates 34. In some embodiments, the second material layers 32B and 34B may be formed on both sidewalls of the floating gate 32 and the control gate 34.

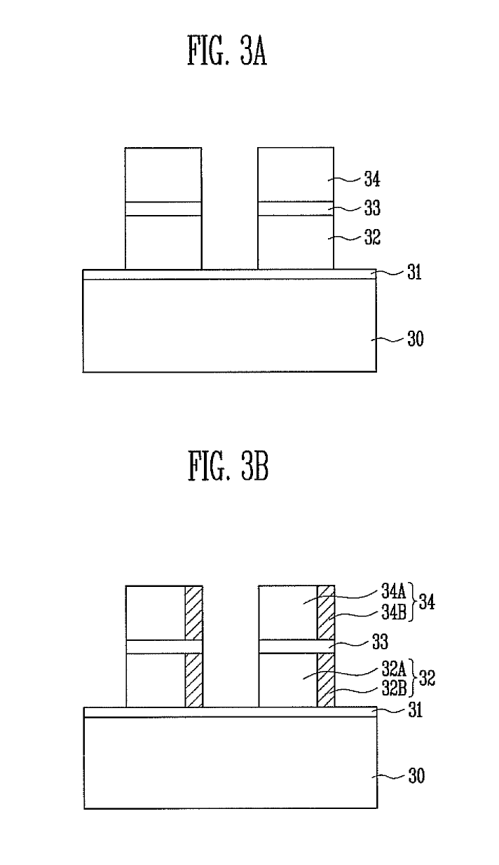

FIGS. 4A and 4B are cross-sectional views illustrating a method of manufacturing a nonvolatile memory device according to a third embodiment of this disclosure.

As shown in FIG. 4A, gate patterns, each including a tunnel insulating layer 41, a floating gate 42, a charge blocking layer 43, and a control gate 44 stacked over a substrate 40, are formed. At least one of the floating gate 42 or the control gate 44 may be formed of a conductive layer, for example, a polysilicon layer.

A reoxidization process may be performed on the resultant structure in which the gate patterns have been formed. As a result of the reoxidization process, an oxide layer having a thickness of 1 to 10 nm is formed on a surface of the gate patterns.

Next, a first region, for example, one or more sidewalls of each of the floating gates 42, are subject to a surface processing so that the first region has a different work function than a second region, which is different than the first region, of the floating gates 42. In the third embodiment, a silicidation process is performed as the surface processing.

For the silicidation process, metal dots 45 are formed on a surface of the floating gate 42 and the control gate 44. The metal dots 45 may be made of metal, such as cobalt (Co), nickel (Ni), or tungsten (W).

The metal dots 45 may be formed on an entire surface of the floating gate 42 and the control gate 44. Alternatively, the metal dots 45 may be formed only the sidewalls of the floating gates 42. For example, the metal dots 45 may be formed on the entire surface of the floating gate 42 and the control gate 44. Then, a sacrificial layer is formed to cover the metal dots 45 that will remain. The metal dots 45 not covered by the sacrificial layer may be removed. In this example, a region in which the metal dots 45 will remain may be determined by the height and pattern of the sacrificial layer. For example, after the sacrificial layer is formed up to the height of the floating gates 42, the metal dots 45 formed on the sidewalls of the control gates 44 may be removed and the metal dots 45 may remain only on the sidewalls of the floating gates 42.

As shown in FIG. 4B, a silicidation process is performed. For example, the metal dots 45 may be reacted with the sidewalls of the floating gates 42 and the control gates 44 by a thermal treatment process, so that a silicide layer having a specific thickness is formed on the sidewalls of the floating gates 42 and the control gates 44.

As a result, the floating gates 42, each including a first material layer 42A formed of the conductive layer and a second material layer 42B formed of the silicide layer, and the control gates 44, each including a first material layer 44A formed of the conductive layer and a second material layer 44B formed of the silicide layer, are formed.

In an exemplary embodiment, the metal dots 45 may be reacted only with the sidewalk of the floating gates 42, so that the floating gates 42, each including the first material layer 42A formed of the conductive layer and the second material layer 42B formed of the silicide layer, and the control gate 44 formed of the conductive layer are formed.

Any metal dots 45 that are not reacted in the thermal treatment process are removed. As a result, the floating gates 42, each including the first material layer 42A formed of the conductive layer and the second material layer 42B formed of the silicide layer, are formed.

Here, the thickness of the metal dots 45 and conditions for the thermal treatment process are controlled so that the second material layers 42B are formed in regions in which they overlap with junctions, as described above with respect to FIGS. 2A-2F.

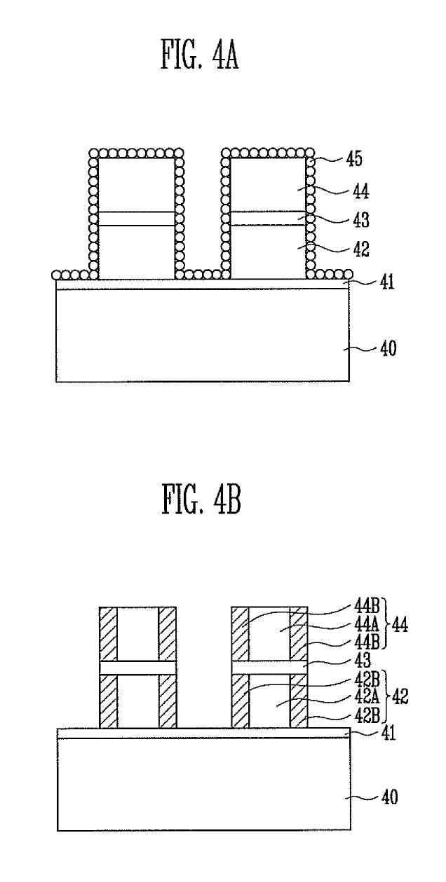

FIGS. 5A and 5B are cross-sectional views illustrating a method of manufacturing a nonvolatile memory device according to a fourth embodiment of this disclosure.

As shown in FIG. 5A, gate patterns, each including a tunnel insulating layer 51, a floating gate 52, a charge blocking layer 53, and a control gate 54 stacked over a substrate 50, are formed. The floating gate 52 may be a conductive layer, for example, a polysilicon layer, and the control gate 54 may be a conductive layer, for example, a polysilicon layer.

A reoxidization process may be performed on the resultant structure in which the gate patterns have been formed. As a result of the reoxidization process, an oxide layer having a thickness of 1 to 10 nm is formed on a surface of the gate patterns

Next, a first region, for example, one or more sidewalls, of each of the floating gates 52 are subject to a surface processing so that the first region has a different work function than a second region, which is different than the first region, of the floating gates 52. In the fourth embodiment, a silicidation process is performed as the surface processing.

For the silicidation process, a metal layer 55 is formed on the surface of floating gate 52 and the control gate 54. The metal layer 55 may be made of metal, such as cobalt (Co), nickel (Ni), or tungsten (W). Here, the metal layer 55 may be formed on an entire surface of the sidewalls of the floating gates 52 or the metal layer 55 may be formed on part of the surface of the sidewalls of the floating gates 52.

As shown in FIG. 5B, the metal layer 55 may be reacted with the sidewalk of the floating gates 52 and the control gates 54 by a thermal treatment process, so that a silicide layer having a specific thickness is formed on the sidewalls of the floating gates 52 and the control gates 54.

Here, the silicide layer may be formed only on the sidewalk of the floating gate 52 or the silicide layer may be formed only on the sidewalls of the control gate 54, depending on a position where the metal layer 55 is formed.

Next, any metal layer 55 not reacted in the thermal treatment process is removed. As a result, the floating gates 52, each including a first material layer 52A formed of the conductive layer and a second material layer 52B formed of the silicide layer, and the control gates 54, each including a first material layer 54A formed of the conductive layer and a second material layer 54B formed of the silicide layer, are formed.

Here, the thickness of the metal layer 55 and conditions for the thermal treatment process are controlled so that the second material layers 52B are formed in regions in which they overlap with junctions (not shown).

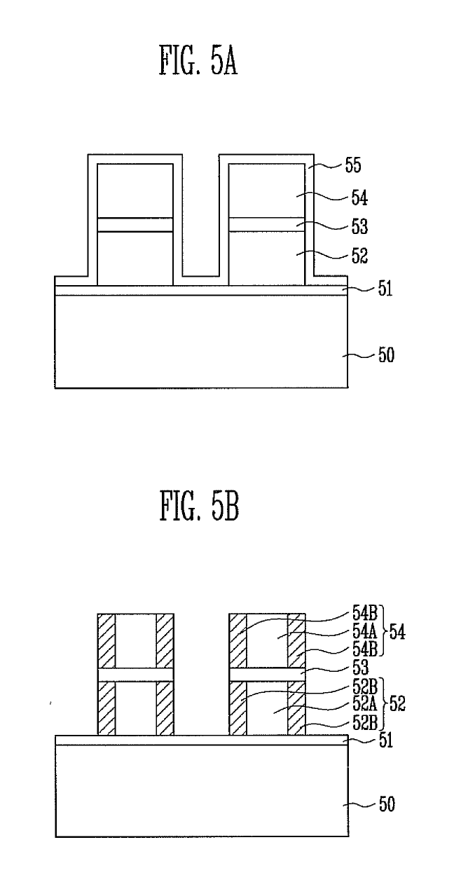

FIGS. 6A to 6C are cross-sectional views illustrating a method of manufacturing a nonvolatile memory device according to a fifth embodiment of this disclosure.

As shown in FIG. 6A, a tunnel insulating layer 61 is formed on a substrate 60. A first conductive layer 62, for floating gates, is formed of two or more layers having different work functions, and is formed on the tunnel insulating layer 61. The first conductive layer 62 may be formed to a thickness of about 1 to about 100 nm.

For example, the first conductive layer 62, formed of two or more layers having different work functions, may be formed by doping impurities.

Next, a mask pattern 63 is formed on the first conductive layer 62. The mask pattern 63 defines regions for floating gates. The mask pattern 63 also defines first regions in which the floating gates and junctions will overlap with each other.

Impurities are doped into the first regions of the first conductive layer 62 that are exposed through the mask pattern 63. Here, the first conductive layer 62 may be formed of a first material layer and doped with a first type of impurity. A second type of impurity may be doped into the first conductive layer 62 using the mask pattern 63 as a barrier by an ion implantation process or a plasma doping process. In some embodiments, two mask patterns may be used so that the second type of impurity may be doped into regions in which the floating gates and the junctions will overlap with each other and the first type of impurity may be doped into regions other than the overlap regions.

As a result, the first conductive layers 62, each including a first material layer 62A doped with the first type of impurity and a second material layer 62B doped with the second type of impurity, are formed.

In an exemplary embodiment, the first conductive layer 62, formed of two or more layers having different work functions, may be formed by a silicidation process.

First, the first conductive layer 62 may be formed of a polysilicon layer. The mask pattern 63, by which the regions for floating gates are exposed, is formed on the first conductive layer 62. The mask pattern 63 may be formed to expose first regions in which the floating gates and the junctions will overlap with each other.

Next, the exposed first regions of the first conductive layer 62 are silicided so that the exposed first regions of the first conductive layer 62 have different work functions from the remaining regions of the first conductive layer 62. For example, metal dots or a metal layer are formed on the resultant structure in which the mask pattern 63 has been formed. The first conductive layer 62 may be silicided by a thermal treatment process, and any unreacted metal dots or any unreacted metal layer may be removed.

As a result, the first conductive layers 62, each including the first material layer 62A, formed of the polysilicon layer, and the second material layer 62B, formed of the silicide layer, are formed.

As shown in FIG. 6B, after removing the mask pattern 63, a charge blocking layer 64 and the second conductive layer 65, both of which form control gates, are formed. Gate patterns are formed by etching the second conductive layer 65, the charge blocking layer 64, and the first conductive layer 62.

As a result, the gate patterns, each of which includes a floating gate 62 that is formed of the first and the second material layers 62A and 62B, which have different work functions, are completed.

In some embodiments, the second conductive layer 65 may also be formed of two or more layers having different work functions.

In another exemplary embodiment, only one of the floating gate or the control gate may be formed of two or more layers having different work functions, or only the control gate may be formed of two or more layers having different work functions.

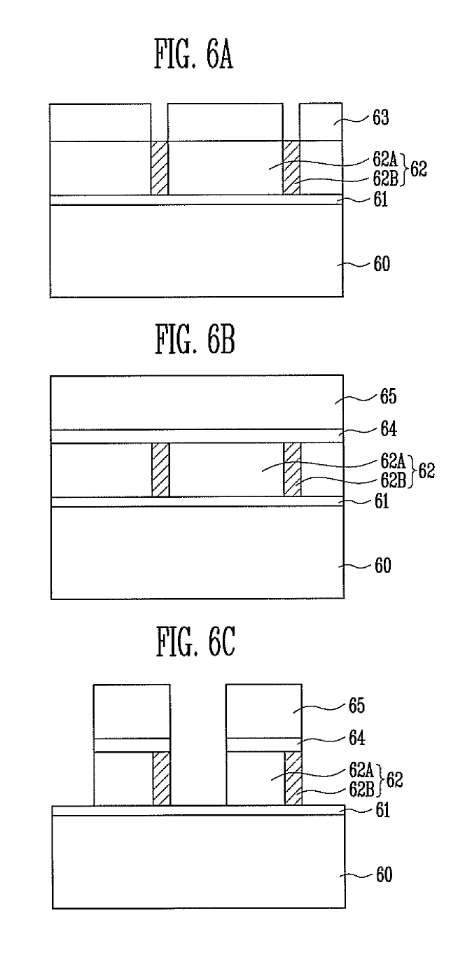

FIG. 7 shows the construction of a memory system according to one embodiment of this disclosure.

As shown in FIG. 7, the memory system 100 includes a non-volatile memory device 120 and a memory controller 110.

The non-volatile memory device 120 is configured to have the above-described cell array. In some embodiments, the non-volatile memory device 120 may be a multi-chip package including a plurality of flash memory chips.

The memory controller 110 is configured to control the nonvolatile memory device 120, and it may include SRAM 111, a central processing unit (CPU) 112, a host interface (I/F) 113, an error correction code (ECC) circuit 114, and a memory interface (I/F) 115. The SRAM 111 is used as the operating memory of the CPU 112. The CPU 112 performs an overall control operation for the data exchange of the memory controller 110. The host I/F 113 is equipped with the data exchange protocol of a host that accesses the memory system 100. Furthermore, the ECC circuit 114 detects and corrects errors included in data read from the nonvolatile memory device 120. The memory I/F 115 performs an interface with the nonvolatile memory device 120. The memory controller 110 may further include RCM for storing code data for an interface with the host.

The memory system 100, configured as described above, may be a memory card or a solid state disk (SSD) in which the nonvolatile memory device 120 and the controller 110 are combined. For example, if the memory system 100 is an SSD, the memory controller 110 may communicate with the outside (for example, a host) through one of various interface protocols, such as a USB, MMC, PCI-E, SATA, PATA, SCSI, ESDI, and IDE.

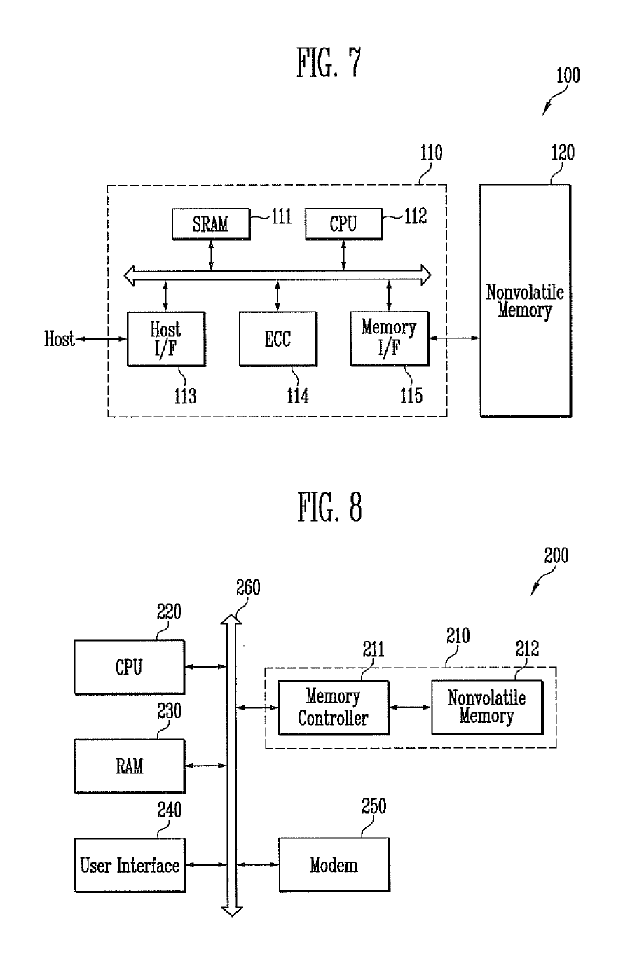

FIG. 8 shows the construction of the construction of a computing system according to one embodiment of this disclosure.

As shown in FIG. 8, the computing system 200 according to the embodiment of this disclosure may include a CPU 220, RAM 230, a user interface 240, a modem 250, and a memory system 210, all of which are electrically coupled to a system bus 260. If the computing system 200 is a mobile device, then the computing system 200 may further include a battery for supplying operating voltages to the computing system 200. The computing system 200 may further include application chipsets, a camera image processor (CIS), mobile DRAM, and so on.

The memory system 210 may include a non-volatile memory device 212 and a memory controller 211, such as those described with reference to shown in FIG. 7.

The nonvolatile memory device includes the floating gates, each including two or more layers having different work functions. In particular, the floating gates are formed so that they have a low work function in regions in which they overlap junctions. Accordingly, both a short channel effect and the generation of GIDL can be prevented.

What is claimed is:

1. A nonvolatile memory device, comprising:
gate patterns, each comprising a tunnel insulating layer, a floating gate, a charge blocking layer, and a control gate, formed over a substrate; and
junctions formed in the substrate, where each of the junctions is to overlap with at least one of the floating gates, and
where each of the floating gates includes a first region that overlaps a corresponding junction, and a second region, that does not overlap the corresponding junction, and where the first region and the second region have different work functions.

2. The nonvolatile memory device of claim 1, wherein:
the second region is formed of a first material layer having a higher work function than the corresponding junction, and
the first region is formed of a second material layer having a lower work function than the corresponding junction.

3. The nonvolatile memory device of claim 1, wherein:
the second region is formed of a first material layer including a first type of impurity, and
the first region is formed of a second material layer including a second type of impurity that is different than the first type of impurity.

4. The nonvolatile memory device of claim 3, wherein the first region comprises one or more sidewalls of the floating gate and the corresponding junction includes the second type of impurity.

5. The nonvolatile memory device of claim 1, wherein:
the first region is formed of a silicide layer, and
the second region is formed of a polysilicon layer.

6. The nonvolatile memory device of claim 1, wherein the control gate includes a third region that overlaps the corresponding junction, and a fourth region that does not overlap the corresponding junction, where the third region and the forth region have different work functions.

7. The nonvolatile memory device of claim 6, wherein:
the fourth region is formed of a third material layer having a higher work function than the corresponding junction, and
the third region is formed of a fourth material layer having a lower work function than the corresponding junction.

8. The nonvolatile memory device of claim 6, wherein:
the fourth region is formed of a third material layer including a first type of impurity, and
the third region is formed of a fourth material layer including a second type of impurity that is different than the first type of impurity.

9. The nonvolatile memory device of claim 8, wherein the third region comprises one or more sidewalls of the control gate and the corresponding junction includes the second type of impurity.

10. The nonvolatile memory device of claim 6, wherein:
the third region is formed of a silicide layer, and
the fourth region is formed of a polysilicon layer.

11. A method of manufacturing a nonvolatile memory device, the method comprising:
forming, over a substrate, gate patterns, each comprising a tunnel insulating layer, a floating gate, a charge blocking layer, and a control gate; and
performing a surface treatment process on each of the floating gates, the surface treatment resulting in a first region of each of the floating gate and a second region of each of the floating gate having different work functions.

12. The method of claim 11, wherein performing the surface treatment process comprises doping the first region with a first type of impurity using an ion implantation process or a plasma doping process.

13. The method of claim 12, wherein, when doping the first type of impurity, junctions are formed in the substrate.

14. The method of claim 11, wherein performing the surface treatment process comprises siliciding the first regions of each of the floating gates.

15. The method of claim 14, wherein performing the surface treatment process comprises:
forming metal dots or a metal layer covering one or more sidewalls of each of the floating gates;
siliciding the one or more sidewalls of each of the floating gates by reacting the one or more sidewalls, of each of the floating gates, with the metal dots or the metal layer using a thermal treatment process; and
removing remaining metal dots or portions of the metal layer.

16. The method of claim 14, wherein performing the surface treatment process comprises:
forming metal dots or a metal layer on an entire surface of the substrate, including the gate patterns;
siliciding sidewalls, of each of the floating gates and each of the control gates, by reacting each of floating gates and each of the control gates with the metal dots or the metal layer using a thermal treatment process; and
removing any remaining metal dots or portions of the metal layer.

17. The method of claim 11, further comprising performing a reoxidization process before performing the surface treatment process.

18. A method of manufacturing a nonvolatile memory device, the method comprising:
forming a tunnel insulating layer on a substrate;
forming a first conductive layer for floating gates on the tunnel insulating layer, where the first conductive layer comprises two or more layers each having a different work function;
forming a charge blocking layer on the first conductive layer;
forming a second conductive layer for control gates on the charge blocking layer; and
forming gate patterns by etching the second conductive layer, the charge blocking layer, and the first conductive layer.

19. The method of claim 18, wherein forming the first conductive layer comprises:
doping the first conductive layer with a first type of impurity;
forming a mask pattern on the first conductive layer, where regions for floating gates are exposed through the mask pattern; and
doping, using the mask pattern as a barrier, the first conductive layer with a second type of impurity that is different than the first type of impurity.

20. The method of claim 18, wherein forming the first conductive layer further comprises:
forming the first conductive layer for floating gates;
forming a mask pattern on the first conductive layer, where regions for floating gates are exposed through the mask pattern; and
siliciding the first conductive layer exposed through the mask pattern.

21. The method of claim 18, wherein the second conductive layer comprises two or more layers, each having different work functions.
